(19) United States
(12) Patent Application Publication
(10) Pub. No.: US 2025/0212332 A1
(43) Pub. Date: Jun. 26, 2025

(54) Circuit board with a memristor and display device having the circuit board

(71) Applicant: InnoLux Corporation, Miao-Li County (TW)

(72) Inventors: Jhe-Ciou JHU, Miao-Li County (TW); Ai-Ling Kuo, Miao-Li County (TW); Wen-Chieh Lin, Miao-Li County (TW)

(73) Assignee: InnoLux Corporation, Miao-Li County (TW)

(21) Appl. No.: 18/955,900

(22) Filed: Nov. 21, 2024

(30) Foreign Application Priority Data
Dec. 22, 2023 (CN) 202311781774.8

(51) Int. Cl. H05K 1/16; G09G 3/32; H05K 1/18

(52) U.S. Cl. CPC H05K 1/167; G09G 3/32; H05K 1/18; G09G 2300/0408; H05K 2201/10128; H05K 2201/10166; H05K 2201/10196

(57) ABSTRACT

A circuit board has a substrate, a plurality of data lines, a plurality of scan lines, and a plurality of unit circuits. The plurality of data lines, the plurality of scan lines, and the plurality of unit circuits are disposed on the substrate. The plurality of unit circuits are defined by intersection of the plurality of data lines and the plurality of scan lines. One of the plurality of unit circuits includes a transistor and a memristor arranged on the substrate. The memristor overlaps with a portion of the transistor.

### BACKGROUND OF THE DISCLOSURE

### 1. Field of the Disclosure

The present disclosure relates to a display device and a circuit board, and in particular, to a display device and a circuit board having a memristor.

### 2. Description of the Prior Art

When the thin-film transistor array process on the substrate is completed, each thin-film transistor is inspected for defects through an array detection system. The traditional way to repair defects in thin-film transistors is to use laser repair. However, laser repair takes a considerable amount of time. In addition, as the pixels on the substrate become smaller, the difficulty of repair correspondingly increases.

### SUMMARY OF THE DISCLOSURE

According to some embodiments, the present disclosure discloses a circuit board comprising a substrate, a plurality of data lines formed on the substrate, a plurality of scan lines formed on the substrate, and a plurality of unit circuits formed on the substrate and defined by intersection of the plurality of data lines and the plurality of scan lines. One of the plurality of unit circuits comprises a transistor formed on the substrate, and a memristor formed on the transistor and overlapping a portion of the transistor.

According to some embodiments, the present disclosure discloses a display device comprising a circuit board and a display medium formed on the circuit board. The circuit board comprises a substrate, a plurality of data lines formed on the substrate, a plurality of scan lines formed on the substrate, and a plurality of unit circuits formed on the substrate and defined by intersection of the plurality of data lines and the plurality of scan lines. One of the plurality of unit circuits comprises a transistor formed on the substrate, and a memristor formed on the transistor and overlapping a portion of the transistor. The circuit board controls a state of the display medium by changing a voltage of the display medium to display an image.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1A is a schematic diagram of a circuit board according to an embodiment of the disclosure.

FIG. 1B shows a unit circuit at an upper right corner of the circuit board in FIG. 1A.

FIG. 2 is a partial sectional view of a display device comprising the circuit board shown in FIG. 1A according to an embodiment of the disclosure.

FIG. 3 is a partial sectional view of the circuit board shown in FIG. 1A.

FIG. 4 is an equivalent circuit diagram of a unit circuit of the circuit board shown in FIG. 1A.

FIG. 5 is a partial sectional view of a circuit board according to another embodiment of the disclosure.

FIG. 6 is an equivalent circuit diagram of a unit circuit of the circuit board shown in FIG. 5.

FIG. 7 illustrates a partial layout of a circuit board according to another embodiment of the disclosure.

FIG. 8 is a partial sectional view of the circuit board shown in FIG. 7, taking along the cross section A-B-A′.

FIG. 9 is a partial sectional view of a circuit board according to another embodiment of the disclosure.

FIG. 10 is a partial sectional view of a circuit board according to another embodiment of the disclosure.

FIG. 11 is a partial sectional view of a circuit board according to another embodiment of the disclosure.

FIG. 12 is a flowchart of testing the circuit board shown in FIG. 1A according to an embodiment of the disclosure.

FIG. 13 is a flowchart of testing the circuit board shown in FIG. 1A according to another embodiment of the disclosure.

### DETAILED DESCRIPTION

To understand the disclosure, please refer to the following detailed description and the attached drawings. It should be noted that in order to make it easier for the reader to understand and for the sake of simplicity of the drawings, many of the drawings in the disclosure only show a portion of the electronic device, and the specific components in the drawings are not drawn to scale. In addition, the number and size of the components in the drawings are for illustrative purposes only and do not limit the scope of the disclosure.

Throughout the specification and appended claims of the disclosure, certain words are used to refer to specific components. It should be understood by those skilled in the art that different manufacturers of electronic devices may refer to the same component by different names. This document does not intend to distinguish between components that have the same function but different names.

In the following specification and claims, the words “comprises,” “contains,” “has,” etc. are open-ended words, and should therefore be interpreted as meaning “including but not limited to . . . ”. Therefore, when the terms “comprises,” “contains,” and/or “has” are used in the description of the disclosure, they specify the existence of the corresponding features, regions, steps, operations, and/or components, but do not exclude the existence of one or more corresponding features, regions, steps, operations, and/or components.

The directional terms used herein, such as “up,” “down,” “front,” “back,” “left,” and “right,” are for reference to the drawings only. Therefore, the directional terms used are for illustrative purposes and do not limit the disclosure. In the drawings, each drawing illustrates the general features of the methods, structures, and/or materials used in a particular embodiment. However, these drawings should not be construed as defining or limiting the scope or nature of the embodiments covered by these embodiments. For example, for the sake of clarity, the relative sizes, thicknesses, and positions of various layers, regions, and/or structures may be reduced or enlarged.

When a corresponding component (such as a layer or region) is referred to as being “on” another component, it may be directly on another component, or there may be other components between the two. On the other hand, when a component is referred to as being “directly on” another component, there are no components between the two. In addition, when a component is referred to as being “on” another component, the two have an up-and-down relationship in the vertical direction, and the component can be above or below the other component, depending on the orientation of the device.

It should be understood that when a component or layer is referred to as being “connected to” another component or layer, it can be directly connected to the other component or layer, or there may be intervening components or layers between the two. When a component is referred to as being “directly connected to” another component or layer, there are no intervening components or layers between the two. In addition, when a component is referred to as being “coupled to another component (or a variation thereof),” it can be directly connected to the other component, or indirectly connected to the other component through one or more intervening components (e.g., electrical connection).

In the disclosure, when one component “electrically connects” to another component, an electrical signal can flow between the two components at least for some time during normal operation; when one component is “coupled” to another component, an electrical signal can flow between the two components at a specified time. In the disclosure, when one component is “disconnected” from another component, an electrical signal cannot flow between the two components at a specified time.

It should be understood that in the specification and claims, the term “horizontal” refers to a direction parallel to the horizontal plane, the term “horizontal plane” refers to a surface parallel to directions X and Y in the drawings, and the term “vertical” refers to a direction parallel to direction Z in the drawings, and directions X, Y, and Z are perpendicular to each other. In the specification and claims, the term “top view” refers to the result of viewing along the vertical direction.

It should be understood that in the specification and claims, the term “overlap” refers to the overlap of two components along the Z direction, and unless otherwise specified, the term “overlap” includes partial or complete overlap.

The terms “approximate” or “about” are generally interpreted as being within a range of plus or minus 10% of the given value, or as being within a range of plus or minus 5%, plus or minus 3%, plus or minus 2%, plus or minus 1%, or plus or minus 0.5% of the given value.

In the specification and claims, the use of ordinal numbers such as “first”, “second”, etc. to modify components does not imply or represent that the component(s) have any prior ordinal number, nor does it represent the order of one component with another component, or the order in the manufacturing method. The use of these ordinal numbers is only to clearly distinguish a component with a certain name from another component with the same name. The specification and claims may not use the same terms, therefore, the first component in the specification may be the second component in the claims.

It should be understood that the following examples can replace, rearrange, and mix the features of several different embodiments to complete other embodiments without departing from the spirit of this disclosure. As long as the features between each embodiment do not violate the spirit of the disclosure or conflict, they can be mixed and matched arbitrarily.

In this disclosure, the electronic device may include a display device, a light-emitting device, an antenna device, a sensing device, a splicing device, or any combination thereof, but not limited thereto. The display device may be a non-self-luminous display or a self-luminous display according to the needs, and may be a color display or a monochrome display according to the needs. The antenna device may be a liquid crystal type antenna device or a non-liquid crystal type antenna device, the sensing device may be a sensing device for sensing capacitance, light, thermal energy or ultrasound, and the splicing device may be a display splicing device or an antenna splicing device, but not limited thereto. The electronic components in the electronic device may include passive components and active components, such as capacitors, resistors, inductors, diodes, transistors, etc. Diodes may include light-emitting diodes (LEDs) or photodiodes. Light-emitting diodes may include organic light-emitting diodes (OLEDs), sub-millimeter light-emitting diodes (mini LEDs), micro light-emitting diodes (micro LEDs) or quantum dot light-emitting diodes (quantum dot LEDs), but not limited thereto. Transistors may include top gate thin film transistors, bottom gate thin film transistors or dual gate thin film transistors, but not limited thereto. The electronic device may also include fluorescence materials, phosphor materials, quantum dot (QD) materials or other suitable materials according to the needs, but not limited thereto. The electronic device may have a driving system, a control system, a light source system, etc. peripheral systems to support the devices and components in the electronic device.

In some embodiments, the circuit board may be a type of electronic device, and the circuit board may be at least a combination of a display device and a touch sensing device, so that the circuit board has at least display and touch sensing functions. The following text uses the circuit board as an example to explain this disclosure, but the design of this disclosure may be applied to any suitable electronic device.

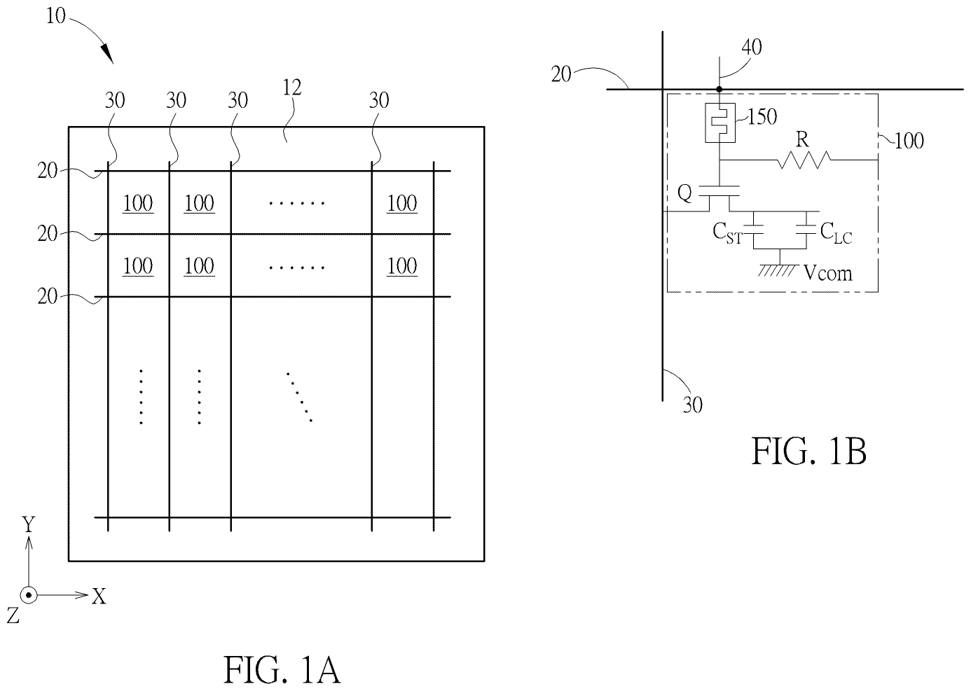

Please refer to FIGS. 1A and 1B. FIG. 1A is a schematic diagram of a circuit board 10 according to an embodiment of the disclosure. FIG. 1B shows a unit circuit 100 at an upper right corner of the circuit board 10. The circuit board 10 comprises a substrate 12, a plurality of scan lines 20, a plurality of data lines 30, and a plurality of unit circuits 100 formed on the substrate 12. The substrate 12 may be rigid or flexible. The substrate 12 comprises suitable materials according to its type. For example, the substrate 12 may comprise glass, quartz, ceramic, sapphire, polymers (such as polyimide (PI), polyethylene terephthalate (PET)), other suitable materials or combinations thereof. The plurality of unit circuits 100 are defined by the intersection of the plurality of scan lines 20 and the plurality of data lines 30.

In this disclosure, the circuit board 10 may comprise at least one conductive layer, at least one insulating layer, at least one semiconductor layer or a combination thereof, these layers are formed on the substrate 12, to form the electronic components of the circuit board 10. The material of the conductive layer may comprise metal, transparent conductive material (such as indium tin oxide (ITO), indium zinc oxide (IZO), etc.), other suitable conductive materials or combinations thereof, but not limited thereto. The material of the insulating layer may comprise silicon oxide (SiOₓ), silicon nitride (SiN_{y}), silicon oxynitride (SiOₓN_{y}), organic insulating materials (e.g., photoresist), other suitable insulating materials or combinations thereof, but not limited thereto. The material of the semiconductor layer may comprise polysilicon, amorphous silicon, metal-oxide semiconductor, other suitable semiconductor materials or combinations thereof, but not limited thereto.

In some embodiments, each of the unit circuits 100 may be a subpixel, but not limited thereto. The unit circuit 100 may comprise a transistor Q, a capacitor C_{LC}, and a capacitor C_{ST}. The gate of the transistor Q is coupled to the scan line 20, a first end of the transistor Q is coupled to the data line 30, and a second end of the transistor Q is electrically connected to the capacitor C_{LC} and the capacitor C_{ST}. The capacitor C_{LC} may be a liquid crystal capacitor, and the capacitor C_{ST} may be a storage capacitor, but not limited thereto. An end of the capacitor C_{LC} and an end of the capacitor C_{ST} are coupled to a common electrode Vcom. The common electrode Vcom may be 0 volts, but not limited thereto.

One of the unit circuits 100 further comprises a memristor 150 formed on the substrate 12. In the embodiment, the memristor 150 is coupled to the gate of the transistor Q. In other embodiments of the disclosure, the memristor 150 is coupled to the drain of the transistor Q. The resistance (or resistive state) of the memristor 150 may be changed by changing the voltage across two ends of the memristor 150. A semiconductor in the memristor 150 may switch between at least two different resistive states, and each resistive state corresponds to a different voltage difference across the two ends of the memristor 150. The two ends of the memristor 150 may be two metal components of the memristor 150, and the resistive state of the memristor 150 may be changed by adjusting the voltage difference between the two metal components. After the fabrication of the transistor Q on the substrate 12 is completed, each transistor Q may be tested for defects using an array testing system. When a unit circuit 100 is detected to be defective due to a defect in the transistor Q, the unit circuit 100 may be repaired by changing the resistance of the memristor 150 of the unit circuit 100. In some embodiments, the bias of the transistor Q in the unit circuit 100 may be adjusted by adjusting the resistance of the memristor 150. Because the memristor 150 is a memory device, and the unit circuit 100 may be a subpixel, the technology disclosed herein is a technology of memory in pixel (MIP).

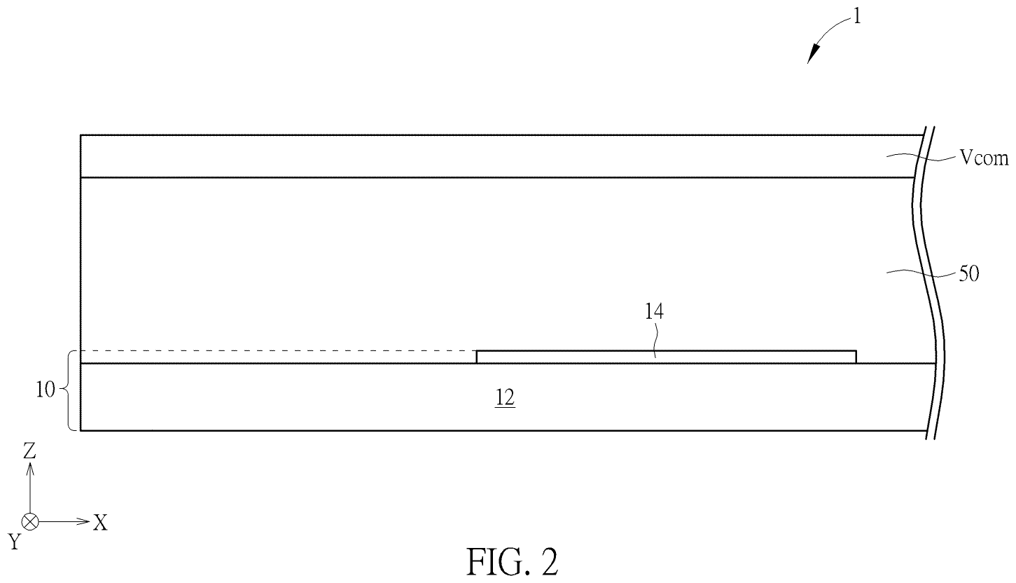

Please refer to FIG. 2, which is a partial sectional view of a display device 1 comprising the circuit board 10 shown in FIG. 1A according to an embodiment of the disclosure. The display device 1 comprises the circuit board 10 and a display medium 50. The display medium 50 is formed on the circuit board 10, and the circuit board 10 controls the state of the display medium 50 by changing a voltage of the display medium 50, thereby enabling the display device 1 to display images. The display medium 50 may be, for example, a liquid crystal. The aforementioned change in the voltage of the display medium 50 is, for example, a change in the voltage difference between a pixel electrode 14 and the common electrode Vcom of the display device 1. In some embodiments, the drain of the transistor Q is electrically connected to the pixel electrode 14, so that the data signal provided by the data line 30 is transmitted to the pixel electrode 14 to control the state of the display medium 50 in the subpixel area. In one embodiment, the drain of the transistor Q may directly contact the pixel electrode 14. In another embodiment, the drain of the transistor Q may be electrically connected to the pixel electrode 14 through a bonding conductive component, but not limited thereto.

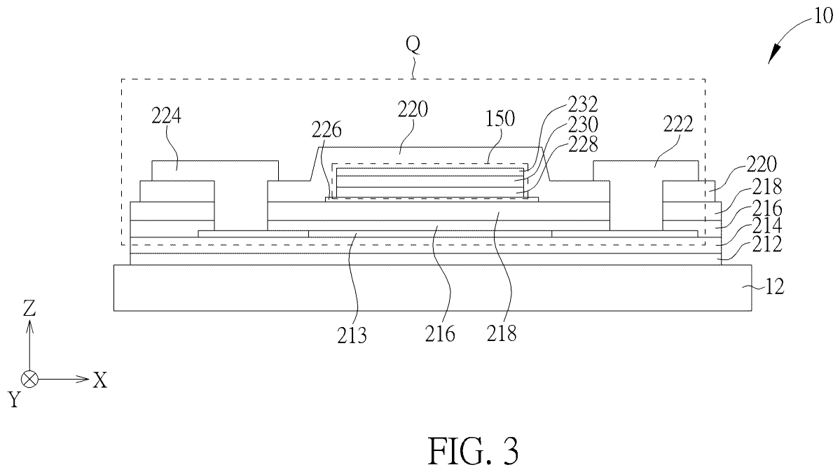

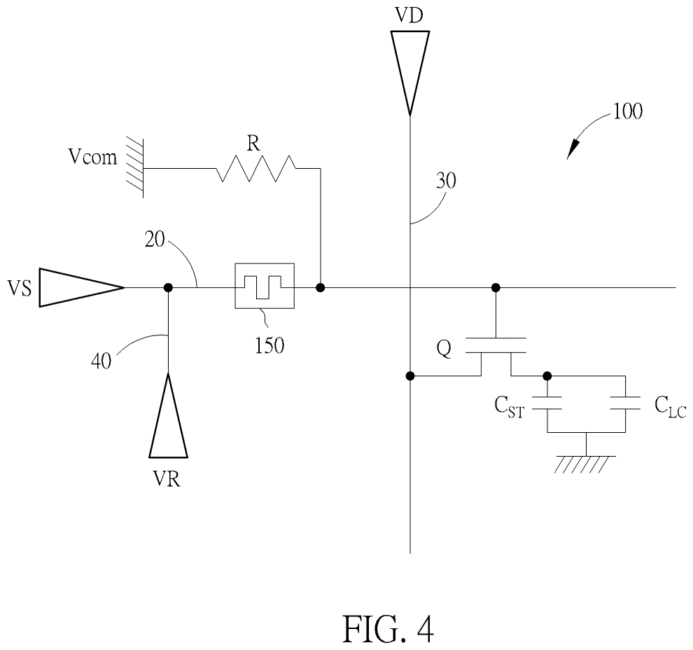

Please refer to FIG. 3 and FIG. 4, FIG. 3 is a partial sectional view of the circuit board 10 shown in FIG. 1A, and FIG. 4 is an equivalent circuit diagram of the unit circuit 100 shown in FIG. 1A. The unit circuit 100 may comprise a transistor Q, a capacitor C_{LC}, a capacitor C_{ST}, and a memristor 150. The circuit board 10 may comprise the substrate 12, an insulating layer 212, an insulating layer 214, an insulating layer 216, an insulating layer 218, an insulating layer 220, a semiconductor 213, a metal component 226, a metal component 228, a semiconductor 230, a metal component 222, the metal component 224, and a metal component 232 shown in FIG. 3. The materials of the insulating layers 212, 214, 216, 218, and 220 may be the same or different, or some of the insulating layers may be the same and other insulating layers may be different. The materials of the insulating layers may include, but are not limited to, silicon nitride (SiNₓ), silicon oxide (SiOₓ), silicon oxynitride (SiOₓN_{y}), epoxy resin, acrylic, bismaleimide, polyimide, or a combination thereof. In one embodiment, the material of the insulating layer 212 is silicon nitride (SiNₓ), and the materials of the insulating layers 214, 216, and 218 are silicon oxide (SiOₓ). The materials of the metal components 222, 224, 226, 228, and 232 may be the same or different, or some of the metal components may be the same and the other metal components may be different. The materials of the metal components may include, but are not limited to, copper (Cu), aluminum (Al), indium (In), ruthenium (Ru), tin (Sn), gold (Au), platinum (Pt), molybdenum (Mo), zinc (Zn), silver (Ag), titanium (Ti), lead (Pb), nickel (Ni), neodymium (Nd), iridium (Ir), chromium (Cr), magnesium (Mg), palladium (Pd), lithium (Li), calcium (Ca), alloys of the foregoing metals, other suitable metal materials, or a combination thereof. In one embodiment, the gate of the transistor Q may be the metal component 226 and the metal component 228 of the same material. The metal components 226 and 228 may be formed by dry etching and wet etching processes, respectively, but this disclosure is not limited thereto. In some embodiments, the gate of the transistor Q may comprise the metal component 228 but not the metal component 226. In one embodiment, the metal components 222, 224, and 226 may be formed by etching the same metal layer. The metal component 222 may be the drain of the transistor Q, the metal component 224 may be the source of the transistor Q, and the semiconductor 213 may be the channel of the transistor Q. In addition, the memristor 150 may comprise the metal component 228, the semiconductor 230, and the metal component 232. At least a part of the memristor 150 overlaps with the transistor Q along the Z direction, and the semiconductor 213 and the semiconductor 230 at least partially overlap along the Z direction, and the width of the semiconductor 213 is greater than the width of the semiconductor 230. The materials of the semiconductor 213 and the semiconductor 230 may be the same or different. The materials of the semiconductor 213 and the semiconductor 230 may include, but are not limited to, indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), or a combination thereof.

Please refer to FIG. 3 and FIG. 4. The metal component 232 of the memristor 150 is coupled to the can line 20. When transistor Q is defective and causes the circuit unit 100 to malfunction, a suitable scanning voltage VS may be applied to one end of the memristor 150 via the scan line 20 to change the resistive state of the memristor 150. The suitable scanning voltage VS may be between 1 volt and 7 volts. In detail, when the scanning voltage VS is applied to the metal component 232 of the memristor 150 via the scan line 20, the voltage difference between the metal component 232 of the memristor 150 and the metal component 228 of the memristor 150 may change, thereby changing the resistive state of the memristor 150. When the metal component 232 and the metal component 228 have a first voltage difference, the semiconductor 230 of the memristor 150 exhibits a first resistive state. When the metal component 232 and the metal component 228 have a second voltage difference different from the first voltage difference, the semiconductor 230 of the memristor 150 exhibits a second resistive state different from the first resistive state. The first resistive state may be a low-resistive state, and the second resistive state may be a high-resistive state. When the resistive state of the memristor 150 is changed (e.g., from the low-resistive state to the high-resistive state), the scanning signal transmitted from the electronic substrate 10 to the scan line 20 cannot be transmitted to the gate of the transistor Q through the high resistance memristor 150, thereby reducing the misoperation of the defective transistor Q. In another embodiment, one end of memristor 150 is coupled to a voltage divider resistor R, and the other end of the memristor 150 is coupled to a read line 40 and the scan line 20. The voltage divider resistor R has a fixed resistance. When it is necessary to determine the resistive state of the memristor 150, a read voltage VR may be applied to the read line 40 coupled to one end of the memristor 150. Then, the resistive state of the memristor 150 may be determined by the voltage at the junction of the memristor 150 and the voltage divider resistor R. For example, if the read voltage VR is 5 volts, when the memristor 150 is in a low resistive state, the voltage at the junction of the memristor 150 and the voltage divider resistor R will approach 5 volts; when memristor 150 is in a high resistive state, the voltage at the junction of the memristor 150 and the voltage divider resistor R will approach 0 volts.

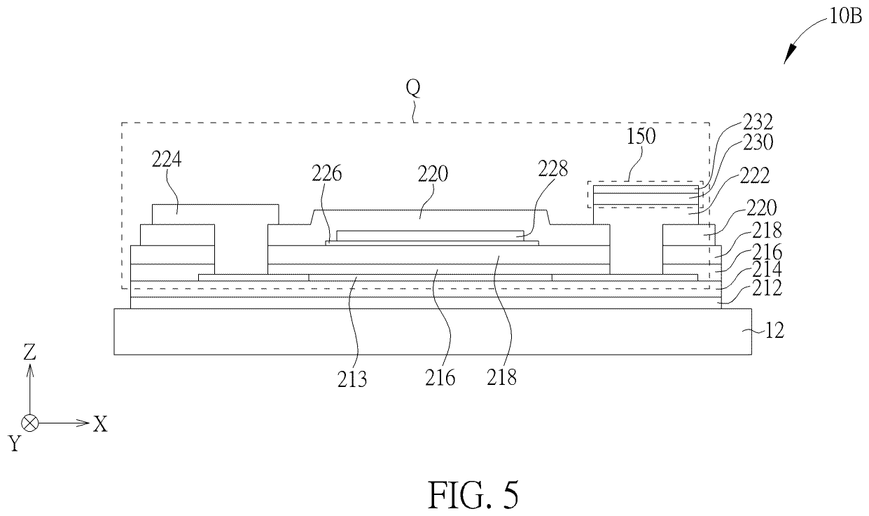

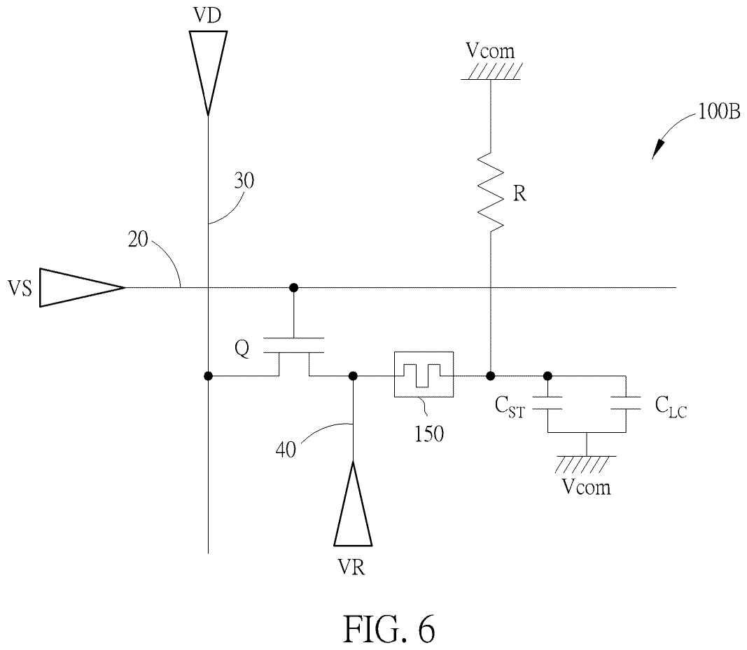

Please refer to FIG. 5 and FIG. 6, FIG. 5 is a partial sectional view of a circuit board 10B of another embodiment of the disclosure, and FIG. 6 is an equivalent circuit diagram of a unit circuit 100B of the circuit board 10B in FIG. 5. The difference between the circuit board 10B and the circuit board 10 in FIG. 3 is that one of the metal components of the memristor 150 in the circuit board 10B is the drain of the transistor Q (i.e., the metal component 222). The memristor 150 may comprise the metal component 222, the semiconductor 230, and the metal component 232. The metal component 232 of the memristor 150 is coupled to the voltage divider resistor R, the capacitor C_{ST}, and the capacitor C_{LC}, and the metal component 222 of the memristor 150 is coupled to the read line 40. When the transistor Q is defective, a suitable read voltage VR may be applied to one end of the memristor 150 via the read line 40 to change the resistive state of the memristor 150. The suitable read voltage VR may be between 1 volt and 7 volts. In detail, when the read voltage VR is applied to the metal component 232 of the memristor 150 via the read line 40, the voltage difference between the metal component 222 of the memristor 150 and the metal component 232 of the memristor 150 may change, thereby changing the resistive state of the memristor 150. When the metal component 222 and the metal component 232 have a first voltage difference, the semiconductor 230 of the memristor 150 exhibits a first resistive state. When the metal component 222 and the metal component 232 have a second voltage difference different from the first voltage difference, the semiconductor 230 of the memristor 150 exhibits a second resistive state different from the first resistive state. The first resistive state may be a low-resistive state, and the second resistive state may be a high-resistive state. When the resistive state of the memristor 150 is changed (e.g., from a low-resistive state to a high-resistive state), the data voltage VD transmitted from the circuit board 10B to the data line 30 cannot be transmitted to the capacitor C_{ST} and the capacitor C_{LC} through the high resistance memristor 150, thereby reducing the misoperation of the defective transistor Q. When it is necessary to determine the resistive state of the memristor 150, the read voltage VR may be applied to the read line 40. Then, the resistive state of the memristor 150 may be determined by the voltage at the junction of the memristor 150 and the voltage divider resistor R.

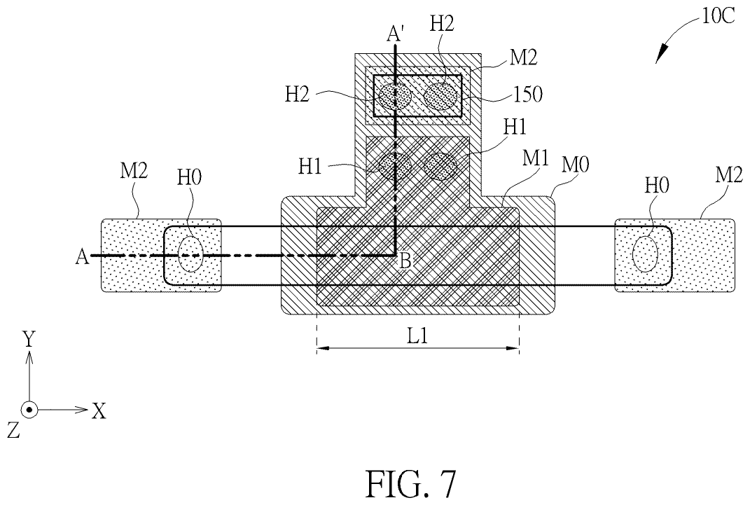

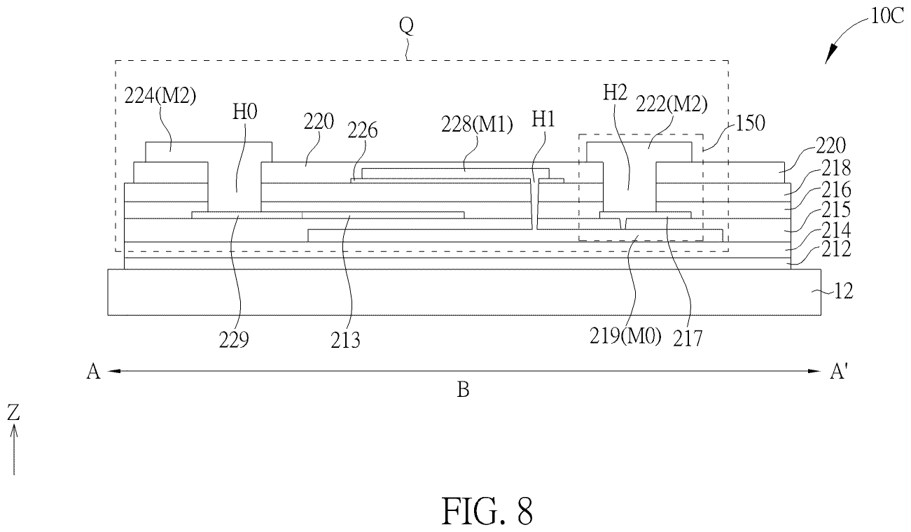

Please refer to FIG. 7 and FIG. 8, FIG. 7 illustrates a partial layout of a circuit board 10C according to another embodiment of the disclosure, and FIG. 8 is a partial sectional view of the circuit board 10C shown in FIG. 7, taking along the cross section A-B-A′. In the embodiment, the transistor Q of the circuit unit in the circuit board 10C is a dual-gate thin-film transistor. The layout shown in FIG. 7 includes the wiring and relative positions of a metal layer M0, a metal layer M1, a metal layer M2, a through hole H0, a through hole H1, and a through hole H2. The circuit unit in the circuit board 10C may comprise a transistor Q, a memristor 150, and the capacitors C_{LC} and C_{ST}. The circuit board 10C may comprise a substrate 12, an insulating layer 212, an insulating layer 214, an insulating layer 215, an insulating layer 216, an insulating layer 218, an insulating layer 220, a semiconductor 213, a semiconductor 217, a metal component 219, a metal component 226, a metal component 228, a doped region 229, a metal component 222, and a metal component 224. The metal components 222 and 224 are formed in the metal layer M2, the metal component 228 is formed in the metal layer M1, and the metal component 219 is formed in the metal layer M0. The metal component 224 is coupled to the doped region 229 via the through hole H0, the metal component 228 is coupled to the metal component 219 via the through hole H1, and the metal component 222 is coupled to the semiconductor 217 via the through hole H2. Furthermore, the top gate electrode of the transistor Q may be the metal components 226 and 228. The metal components 226 and 228 may be made of the same material, and may be formed by a dry etching and wet etching process, respectively, but the disclosure is not limited thereto. The metal component 219 may be the bottom gate electrode of the transistor Q, the metal component 228 may be the source electrode of the transistor Q, and the metal component 222 may be the drain electrode of the transistor Q. In addition, the memristor 150 of the circuit unit in the circuit board 10C may comprise the metal component 222, the semiconductor 217, and the metal component 219. In other words, the metal component 219 may be a part of the memristor 150 or the bottom gate electrode of the transistor Q. The equivalent circuit of the circuit unit in the electronic substrate 10C may be consistent with the equivalent circuit of the unit circuit 100 in FIG. 4.

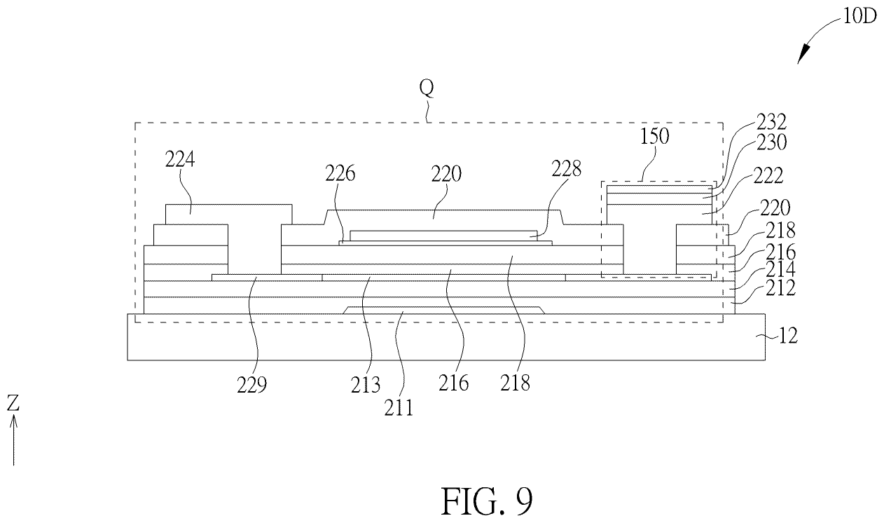

Please refer to FIG. 9, which is a partial sectional view of a circuit board 10D according to another embodiment of the disclosure. The transistor Q of the unit circuit in the circuit board 10D is a dual gate thin film transistor. The circuit board 10D may comprise a substrate 12, an insulating layer 212, an insulating layer 214, a metal component 211, an insulating layer 216, an insulating layer 218, an insulating layer 220, a semiconductor 213, a metal component 226, a metal component 228, a doped region 229, a semiconductor 230, a metal component 222, a metal component 232, and a metal component 224. The metal component 228 may be the top gate electrode of the transistor Q, the metal component 211 may be the bottom gate electrode of the transistor Q, the metal component 224 may be the source of the transistor Q, and the metal component 222 may be the drain of the transistor Q. In addition, the memristor 150 of the unit circuit in the circuit board 10D comprises the metal component 232, the semiconductor 230, and the metal component 222. In other words, the metal component 222 may be a part of the memristor 150 and may also be the drain of the transistor Q. The equivalent circuit of the circuit unit in the electronic substrate 10D may be consistent with the equivalent circuit of the unit circuit 100B in FIG. 6.

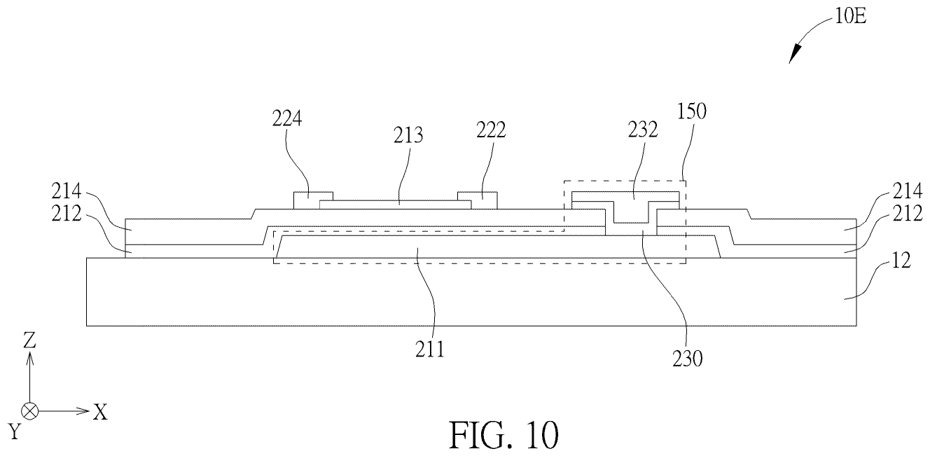

Please refer to FIG. 10, which is a partial sectional view of a circuit board 10E according to another embodiment of the disclosure. The transistor Q of the unit circuit in the circuit board 10E is a bottom gate type thin film transistor. In the embodiment, the circuit board 10E may comprise a substrate 12, an insulating layer 212, an insulating layer 214, a metal component 211, a semiconductor 213, a metal component 222, a semiconductor 230, a metal component 232, and a metal component 224. The semiconductor 230 is formed between the metal component 211 and the metal component 232. In addition, the metal component 211 may be the gate electrode of the transistor Q, the metal component 224 may be the source of the transistor Q, and the metal component 222 may be the drain of the transistor Q. The memristor 150 of the unit circuit in the circuit board 10E comprises the metal component 232, the semiconductor 230, and the metal component 211. In other words, the metal component 211 may be a part of the memristor 150 and may also be the gate electrode of the transistor Q. The equivalent circuit of the circuit unit in the electronic substrate 10E may be consistent with the equivalent circuit of the unit circuit 100 in FIG. 4.

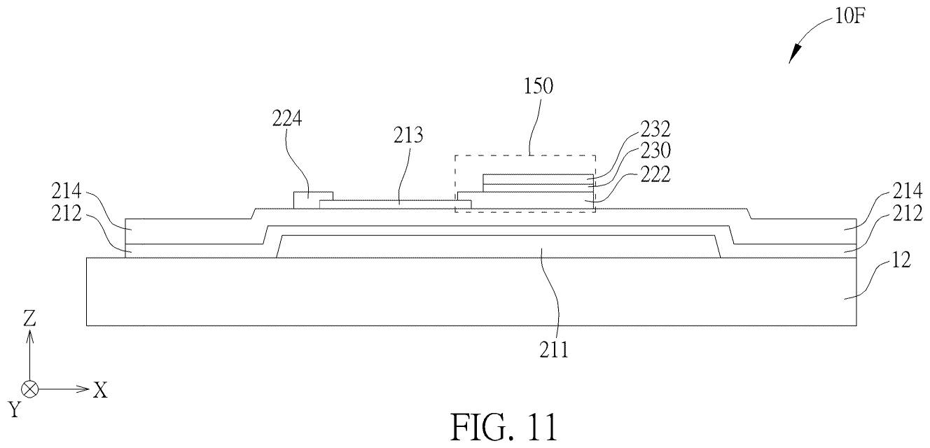

Please refer to FIG. 11, which is a partial sectional view of a circuit board 10F according to another embodiment of the disclosure. The transistor Q of the unit circuit in the circuit board 10F is a bottom gate type thin film transistor. The circuit board 10F may comprise a substrate 12, an insulating layer 212, an insulating layer 214, a metal component 211, a semiconductor 213, a metal component 222, a semiconductor 230, a metal component 232, and a metal component 224. The semiconductor 230 is formed between the metal component 232 and the metal component 222. In addition, the metal component 211 may be the gate electrode of the transistor Q, the metal component 224 may be the source of the transistor Q, and the metal component 222 may be the drain of the transistor Q. The memristor 150 of the unit circuit in the circuit board 10F comprises the metal component 232, the semiconductor 230, and the metal component 222. In other words, the metal component 222 may be a part of the memristor 150 and may also be the drain of the transistor Q. The equivalent circuit of the circuit unit in the electronic substrate 10F may be consistent with the equivalent circuit of the unit circuit 100B in FIG. 6.

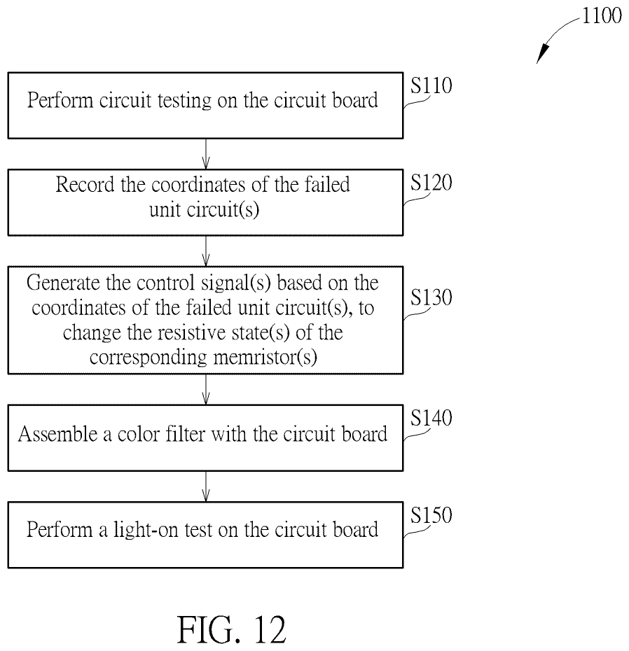

Please refer to FIG. 12, which is a flowchart of a method 1100 for testing the circuit board 10 shown in FIG. 1A according to an embodiment of the disclosure. The method 1100 comprises the following steps:
Step S110: Perform circuit testing on the circuit board 10;
Step S120: Record the coordinates of the failed unit circuit(s) 100;
Step S130: Generate the control signal(s) based on the coordinates of the failed unit circuit(s): 100, to change the resistive state(s) of the corresponding memristor(s) 150;
Step S140: Assemble a color filter with the circuit board 10; and
Step S150: Perform a light-on test on the circuit board 10.

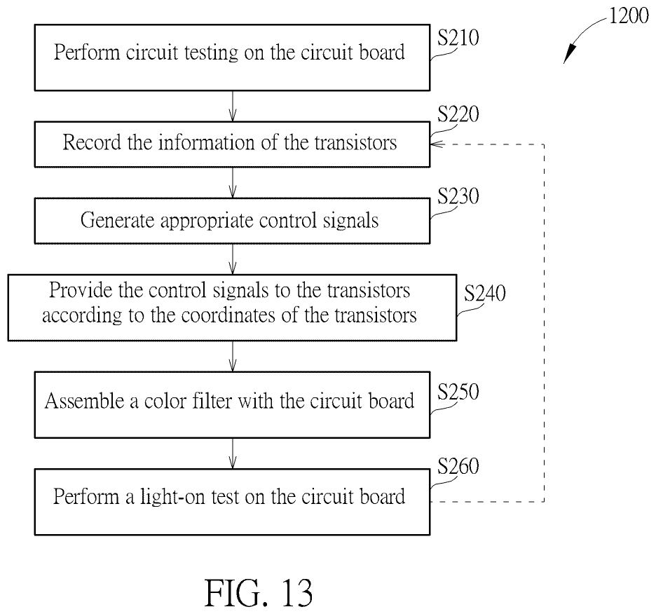

Please refer to FIG. 13, which is a flowchart of a method 1200 for testing the circuit board 10 shown in FIG. 1A according to another embodiment of the disclosure. The method 1200 comprises the following steps:
Step S210: Perform circuit testing on the circuit board 10;
Step S220: Record the information of the transistors Q (e.g., a voltage-current curve of each transistor Q, the coordinates of each transistor Q, whether there is any transistor Q corresponding to a bright spot, etc.);
Step S230: Generate appropriate control signals;
Step S240: Provide the control signals to the transistors Q according to the coordinates of the transistors Q;
Step S250: Assemble a color filter with the circuit board 10; and
Step S260: Perform a light-on test on the circuit board 10.

The disclosure combines the memristor with the unit circuit of the display device. By changing the resistive state of the memristor, the failed unit circuit may be repaired. In addition, based on the circuit characteristics of each unit circuit, it may be decided whether to repair the unit circuit through the corresponding memristor. Therefore, it may greatly save the time required for testing and repairing the circuit board of the display device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A circuit board, comprising:
a substrate;
a plurality of data lines, formed on the substrate;
a plurality of scan lines, formed on the substrate; and
a plurality of unit circuits, formed on the substrate and defined by intersection of the plurality of data lines and the plurality of scan lines, where one of the plurality of unit circuits comprises:
a transistor, formed on the substrate; and
a memristor, formed on the transistor and overlapping a portion of the transistor.

2. The circuit board of claim 1, wherein the memristor comprises a first metal component, a first semiconductor and a second metal component, and the first semiconductor is formed between the first metal component and the second metal component.

3. The circuit board of claim 2, wherein when the first metal component and the second metal component have a first voltage difference, the first semiconductor exhibits a first resistive state; and
wherein when the first metal component and the second metal component have a second voltage difference different from the first voltage difference, the first semiconductor exhibits a second resistive state different from the first resistive state.

4. The circuit board of claim 2, wherein the transistor comprises a second semiconductor and a gate, and the gate is formed on the second semiconductor and is the first metal component of the memristor.

5. The circuit board of claim 4, wherein the first semiconductor and the second semiconductor at least partially overlap.

6. The circuit board of claim 4, wherein a width of the second semiconductor is greater than a width of the first semiconductor.

7. The circuit board of claim 2, wherein the transistor comprises a second semiconductor and a drain, and the drain is formed on the second semiconductor and is the first metal component of the memristor.

8. The circuit board of claim 7, wherein the first semiconductor and the second semiconductor at least partially overlap.

9. The circuit board of claim 7, wherein a width of the second semiconductor is greater than a width of the first semiconductor.

10. The circuit board of claim 1, wherein each of the unit circuits is a subpixel.

11. A display device, comprising:
a circuit board, comprising:
a substrate;
a plurality of data lines, formed on the substrate;
a plurality of scan lines, formed on the substrate; and
a plurality of unit circuits, formed on the substrate and defined by intersection of the plurality of data lines and the plurality of scan lines, where one of the plurality of unit circuits comprises:
a transistor, formed on the substrate; and
a memristor, formed on the transistor and overlapping a portion of the transistor; and
a display medium, formed on the circuit board, wherein the circuit board controls a state of the display medium by changing a voltage of the display medium to display an image.

12. The display device of claim 11, wherein the memristor comprises a first metal component, a first semiconductor and a second metal component, and the first semiconductor is formed between the first metal component and the second metal component.

13. The display device of claim 12, wherein when the first metal component and the second metal component have a first voltage difference, the first semiconductor exhibits a first resistive state; and
wherein when the first metal component and the second metal component have a second voltage difference different from the first voltage difference, the first semiconductor exhibits a second resistive state different from the first resistive state.

14. The display device of claim 12, wherein the transistor comprises a second semiconductor and a gate, and the gate is formed on the second semiconductor and is the first metal component of the memristor.

15. The display device of claim 14, wherein the first semiconductor and the second semiconductor at least partially overlap.

16. The display device of claim 14, wherein a width of the second semiconductor is greater than a width of the first semiconductor.

17. The display device of claim 12, wherein the transistor comprises a second semiconductor and a drain, and the drain is formed on the second semiconductor and is the first metal component of the memristor.

18. The display device of claim 17, wherein the first semiconductor and the second semiconductor at least partially overlap.

19. The display device of claim 17, wherein a width of the second semiconductor is greater than a width of the first semiconductor.

20. The display device of claim 11, wherein each of the unit circuits is a subpixel.
